(19) United States
(12) Patent Application Publication
(10) Pub. No.: US 2024/0429121 A1
(43) Pub. Date: Dec. 26, 2024

(54) Power Module and Method for Assembling a Power Module

(71) Applicant: ZF Friedrichshafen AG, Friedrichshafen (DE)

(72) Inventors: Wei Liu, Friedrichshafen (DE); Mitsutoshi Muraoka, Friedrichshafen (DE)

(21) Appl. No.: 18/703,792

(22) PCT Filed: Oct. 28, 2022
(86) PCT No.: PCT/EP2022/080204

§ 371 Date: Apr. 23, 2024

(30) Foreign Application Priority Data
Oct. 29, 2021 (DE) 10 2021 212 232.9

(51) Int. Cl. H01L 23/367; H01L 21/48; H01L 23/00; H01L 23/31; H01L 23/373; H01L 23/40; H01L 23/538; H01L 25/00; H01L 25/065

(52) U.S. Cl. CPC H01L 23/3675; H01L 21/4882; H01L 23/3142; H01L 23/3735; H01L 25/0655; H01L 25/50; H01L 23/40; H01L 23/538; H01L 24/32; H01L 2224/32245

(57) ABSTRACT

A power module (20) includes: a chip arrangement (24) with a carrier (40) and at least one electronic component (42) assembled on the carrier (40); a heat sink (22)) with a first layer (30), an electrically insulating second layer (32) located on the first layer (30), and an electrically conductive third layer (34) located on the second layer (32); and an arrangement body (26) arranged between the chip arrangement (24) and the heat sink (22), with at least one contact recess (50, 52) through which the chip arrangement (24) is thermally coupled to the heat sink (22), and formed and arranged such that a form fit is provided between the arrangement body (26) and the heat sink (22) in a direction extending parallel to at least one of the layers (30, 32, 34) of the heat sink (22) and between the arrangement body (26) and the chip arrangement (24) in a direction extending parallel to the carrier (40) of the chip arrangement (24).

### CROSS-REFERENCE TO RELATED APPLICATIONS

The present application is related and has right of priority to German Patent Application No. DE102021212232.9 filed on Oct. 29, 2021 and is a U.S. national phase of PCT/EP2022/080204 filed on Oct. 28, 2022, both of which are incorporated by reference in their entirety for all purposes.

### TECHNICAL FIELD

The present invention relates generally to a power module and a method for manufacturing a power module.

### BACKGROUND

A conventional power module may include a heat sink and a chip arrangement assembled on the heat sink. The heat sink may include a DBC (Direct Bonded Copper, in German: direkt gebondetes Kupfer) substrate or an IMS (Insulated Metal Substrate, in German: isoliertes Metallsubstrat). The chip arrangement may include a carrier and at least one electronic component assembled on the carrier. At least a part (e.g., the electronic components) of the chip arrangement may be in thermal contact, for example, direct physical contact, with the heat sink.

The electronic component may include an active electronic component and/or a passive electronic component. The passive electronic component may include a resistor, a capacitor, and/or a conductor. The active electronic component may include a chip and/or a transistor. The active electronic component may be configured as a high-speed switching device. The active electronic component may be configured as a high-performance semiconductor device. The chip arrangement may include two or more of the electronic components mentioned above, wherein the electronic components may be arranged on a first side of the carrier facing the heat sink, or wherein the electronic components may be arranged on a second side of the carrier facing away from the heat sink, or wherein some of the electronic components may be arranged on the first side of the carrier and some of the electronic components may be arranged on the second side of the carrier.

In an assembling process of the power module, the chip arrangement is assembled on the heat sink. Especially, the chip arrangement is first arranged on the heat sink, it being important that the chip arrangement is positioned accurately on the heat sink. This may be a challenge, especially if one or more electronic components are arranged on the carrier in such a way that the weight of the one or more electronic components is non-uniformly distributed across the carrier, because the carrier may be tilted relative to the heat sink after the chip arrangement is arranged on the heat sink. The chip arrangement may be fixed to the heat sink by using a die bonding process. In the die bonding process, at least a part of the chip arrangement (e.g., an electronic component of the chip arrangement) is sintered, bonded, adhered or soldered to the heat sink. Accurate positioning of the chip arrangement on the heat sink may lead to poor thermal conductivity between the chip arrangement and the heat sink, and thus to poor heat dissipation from the chip arrangement. This may lead to poor cooling of the chip arrangement and may reduce the power of the one or more electronic components of the chip arrangement.

JP 5607829 B2 provides a chip arrangement in which two chips are arranged between two DBC substrates in a housing. The chips are fixed in recesses of the housing with an adhesive and a silicone gel. Due to the at least partially liquid state in which the adhesive and the silicone gel must be during application, the chips within the recesses may deviate from their intended positions in a lateral direction, which may cause inaccurate positioning and thus cause a problem during electrical contact.

### BRIEF SUMMARY

Example aspects of the present invention provide a power module, including at least one electronic component. The power module can be assembled easily, accurately, and/or quickly. The power module enables the high performance of the electronic component, and/or the power module enables appropriate cooling of the electronic component.

Another example aspect of the present invention provides a method for assembling a power module, the power module including at least one electronic component. The method can be performed easily, accurately, and/or quickly. The power module contributes to high performance of the electronic component, and/or the method contributes to appropriate cooling of the electronic component.

In an example aspect, a power module includes: a chip arrangement, which includes a carrier and at least one electronic component assembled on the carrier; a heat sink, which includes an electrically conductive first layer, an electrically insulating second layer located on the first layer, and an electrically conductive third layer located on the second layer; and an arrangement body, which is arranged between the chip arrangement and the heat sink and includes at least one contact recess through which the chip arrangement is thermally coupled to the heat sink and which is formed and arranged in such a way that there is a form fit between the arrangement body and the heat sink in a direction extending parallel to the layers of the heat sink and between the arrangement body of the chip arrangement in a direction extending parallel to the carrier of the chip arrangement.

The provision of the arrangement body in form fit with the heat sink and in form fit with the chip arrangement enables the power module to be easily, accurately, and/or rapidly assembled, and/or contributes to the appropriate cooling of the electronic component and thus contributes to the high performance of the electronic component.

The electronic component may be an active electronic component (e.g., a chip or a transistor) or a passive electronic component (e.g., a resistor, a capacitor or a choke coil). The active electronic component may include a semiconductor die. The semiconductor die may contain SiC, GaN or GaO. The chip arrangement may include two or more electronic components. Some of the electronic components may be arranged on a first side of the carrier facing the heat sink. Alternatively or additionally, some of the electronic components may be arranged on a second side of the carrier facing away from the heat sink. The carrier may be a printed circuit board (PCB). The direction extending parallel to the layers of the heat sink and the direction extending parallel to the carrier of the chip arrangement may extend parallel to each other.

According to an example implementation, the form fit between the arrangement body and the heat sink may be provided by a heat sink recess in the arrangement body, with the heat sink being at least partially arranged in the heat sink recess; and/or by at least one third layer recess in the arrangement body with at least one section of the third layer of the heat sink being arranged in the third layer recess. By providing the heat sink recess and/or the third layer recess, it possible to provide, in a simple and safe manner, the form fit between the arrangement body and the heat sink in the direction extending parallel to the layers of the heat sink.

The heat sink may be at least partially arranged in the heat sink recess with a clearance fit or an interference fit between an inner side wall of the heat sink recess and an outer edge of the heat sink. The third layer may be at least partially arranged in the third layer recess with a clearance fit or an interference fit between an inner side wall of the third layer recess and an outer edge of the corresponding section of the third layer. If the chip arrangement is thermally coupled to the heat sink by the third layer recess, the third layer recess may form a part of the contact recess or be equivalent to the contact recess. The third layer recess may be a through recess extending from a first side of the arrangement body to a second side of the arrangement body, wherein the first side of the arrangement body faces the heat sink, and the second side of the arrangement body faces the chip arrangement. In comparison, the heat sink recess may only extend partially from the first side of the arrangement body to the second side of the arrangement body, and may include a bottom in the arrangement body. Furthermore, the third layer recess may be arranged in the heat sink recess and/or open into the heat sink recess.

According to an example implementation, the form fit between the arrangement body and the chip arrangement may be provided by a recess for an electronic component in the arrangement body, with the electronic component of the chip arrangement being at least partially arranged in the recess for the electronic component; and/or by at least one pin of the arrangement body, which is arranged in a corresponding pin recess in the carrier of the chip arrangement. By providing the recess for the electronic component and/or the pin and by providing the pin recess, it possible to provide, in a simple manner, the form fit between the arrangement body and the chip arrangement in the direction extending parallel to the carrier of the chip arrangement.

The electronic component may be at least partially arranged in the recess for the electronic component with a clearance fit or an interference fit between an inner side wall of the recess for the electronic component and an outer edge of the corresponding electronic component. The pin may be at least partially arranged in a pin arrangement with a clearance fit or an interference fit between an inner side wall of the pin recess and an outer edge of the corresponding pin. The pin recess may be a through recess extending from a first side of the carrier to a second side of the carrier. The recess for the electronic component may be a through recess extending from the first side of the arrangement body to the second side of the arrangement body. If the chip arrangement is thermally coupled to the heat sink by the recess for the electronic component, the recess for the electronic component may be equivalent to the contact recess. Alternatively, the recess for the electronic component and the third layer recess may overlap completely and thus form a single contact recess.

According to an example implementation, the thermal coupling between the chip arrangement and the heat sink is provided by direct physical contact between the heat sink and the chip arrangement or by a connecting material that firmly couples the chip arrangement to the heat sink. The direct physical contact or firm connection between the chip arrangement and the heat sink may be provided by the direct physical contact or firm connection between the carrier of the chip arrangement and the third layer of the heat sink and/or between the electronic component of the chip arrangement and the third layer of the heat sink. In this way, it is possible to provide, in an efficient and simple manner, the thermal coupling between the chip arrangement and the heat sink.

If the chip arrangement is thermally coupled to the heat sink by the thermal coupling between the electronic component and the third layer of the heat sink, the electronic component may be arranged in the recess for the electronic component of the arrangement body, wherein the corresponding recess for the electronic component may be equivalent to the contact recess.

According to an example implementation, the arrangement body is formed and arranged in such a way that at least one cavity between the chip arrangement and the heat sink is filled by the arrangement body. In this arrangement, the heat sink and the arrangement body provide a stable and/or continuous basis for the chip arrangement. In this way, even if the weight of the one or more electronic components is non-uniformly distributed over the carrier, accurate positioning of the chip arrangement on the heat sink can also be achieved, and the tilting of the chip arrangement relative to the heat sink can be avoided. This contributes to a very good thermal coupling between the chip arrangement and the heat sink, and thus to a very good heat dissipation from the chip arrangement. Furthermore, this may further contribute to the high performance of the electronic component and thus of the power module. The term “filled” used herein may mean “completely filled”. Therefore, the cavity may be filled completely by the arrangement body. For example, any cavity between the chip arrangement and the heat sink may be filled by the arrangement body.

According to an example implementation, the heat sink is a directly bonded copper substrate or an insulated metal substrate. This contributes to a very good heat dissipation from the chip arrangement.

According to an example implementation, the electronic component or at least one further electronic component of the chip arrangement is a high-performance semiconductor chip. The high-performance semiconductor chip may be configured to treat a high voltage, for example greater than one hundred volts (100 V), and/or a high current, for example greater than ten amps (10 A).

The example features, implementations, and/or advantages associated with the power module described above may also relate to example features, implementations and/or advantages of a method for assembling a power module. Example aspects of the method will be explained below.

In another example aspect, the present invention relates to a method for assembling a power module, wherein the method includes: providing a heat sink having an electrically conductive first layer, an electrically insulating second layer located on the first layer, and an electrically conductive third layer located on the second layer; arranging an arrangement body having a contact recess on the heat sink, wherein the arrangement body is formed and arranged in such a way that there is a form fit between the arrangement body and the heat sink in a direction extending parallel to at least one of the layers of the heat sink; and arranging a chip arrangement, which has a carrier and at least one electronic component assembled on the carrier, on the arrangement body, wherein the arrangement body and the chip arrangement are formed and arranged in such a way that the heat sink and the chip arrangement are thermally coupled to each other by the contact recess, and there is a form fit between the arrangement body and the chip arrangement in a direction extending parallel to the carrier of the chip arrangement.

According to an example implementation, the form fit between the arrangement body and the heat sink is provided by a heat sink recess in the arrangement body, with the heat sink being at least partially arranged in the heat sink recess, and/or by at least one third layer recess in the arrangement body, with at least one section of the third layer of the heat sink being arranged in the third layer recess.

According to an example implementation, the form fit between the arrangement body and the chip carrier is provided by a recess for an electronic component in the arrangement body, with the electronic component of the chip arrangement being at least partially arranged in the recess for the electronic component, and/or by at least one pin of the arrangement body, which is arranged in a corresponding pin recess in the carrier of the chip arrangement.

According to an example implementation, the arrangement body is formed and arranged in such a way that at least one cavity between the chip arrangement and the heat sink is filled by the arrangement body.

According to an example implementation, the method further includes: providing at least one connecting material in a region, which is configured for the thermal coupling between the heat sink and the chip arrangement, between the heat sink and the chip arrangement, such that the connecting material is in direct physical contact with the heat sink and the chip arrangement; heating the first layer of the heat sink such that heat is transferred from the first layer of the heat sink to the connecting material through the second and third layers and at least partially melts the connecting material; and cooling the power module such that the connecting material is solidified and the chip arrangement is firmly connected to the heat sink via the solidified connecting material.

The connecting material may be arranged such that the connecting material is in direct physical contact with the third layer of the heat sink and the electronic component, and/or that the connecting material is in direct physical contact with the third layer of the heat sink and the carrier of the chip arrangement. The connecting material may be a solder or an electrically conductive adhesive.

These and other aspects of the present invention will be apparent and explained with reference to implementations described below.

### BRIEF DESCRIPTION OF THE DRAWINGS

Exemplary embodiments of the invention are explained in greater detail in the following with reference to the drawings.

FIG. 1 shows a cross-sectional side view of a power module according to an example embodiment of the present invention.

FIG. 2 shows a top view of a heat sink of the power module according to FIG. 1.

FIG. 3 shows a bottom view of a chip arrangement of the power module according to FIG. 1.

FIG. 4 shows a top view of an arrangement body of the power module according to FIG. 1.

FIG. 5 shows a flowchart of a method for assembling a power module according to an example embodiment of the present invention.

The reference signs used in the drawings and their meanings are listed in summary form in the list of reference signs. In principle, identical components in the drawings are provided with the same reference signs.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

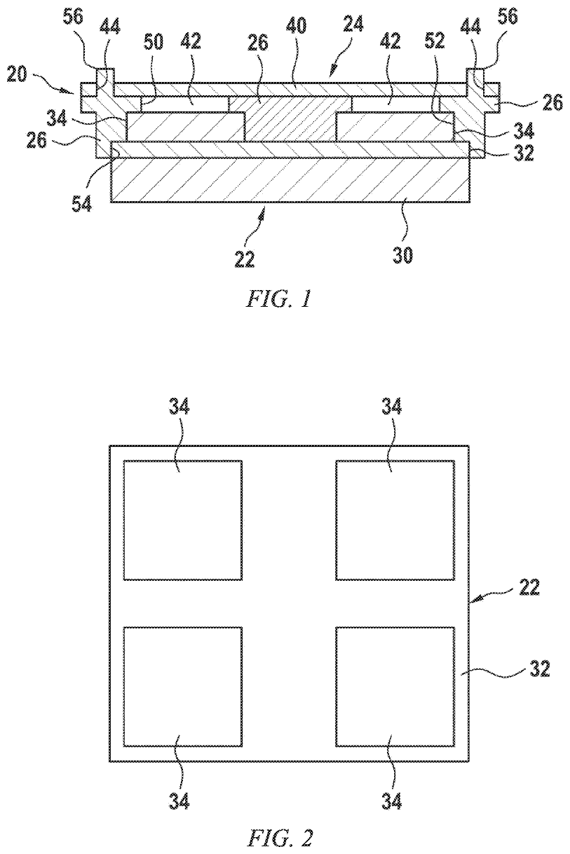

FIG. 1 shows a cross-sectional side view of a power module 20 according to an example embodiment of the present invention. Especially, FIG. 1 shows the power module 20 in the assembled state. The power module 20 includes a chip arrangement 24, a heat sink 22, and an arrangement body 26. The power module 20 may provide one or more half-bridges that may be used in an inverter and/or a rectifier.

The chip arrangement 24 includes a carrier 40 and at least one electronic component 42 assembled on the carrier 40. The electronic component 42 may be an active electronic component (e.g., a chip or a transistor) or a passive electronic component (e.g., a resistor, a capacitor or a choke coil). The chip arrangement 24 may include two or more electronic components 42. The electronic components 42 are arranged on a first side of the carrier 40 facing the heat sink 22. Alternatively or additionally, some of the electronic components 42 may be arranged on a second side of the carrier 40 facing away from the heat sink 22. The carrier 40 may be a printed circuit board (PCB). A surface of the carrier 40 may be greater than a surface of the heat sink 22, so that the carrier 40 extends beyond an outer edge of the heat sink 22.

At least one of the electronic components 42 of the chip arrangement 24 may be a high-performance semiconductor chip. The high-performance semiconductor chip may be configured to treat a high voltage, for example greater than one hundred volts (100 V), and/or a high current, for example greater than ten amps (10 A). The active electronic component may include a semiconductor die. The semiconductor die may contain SiC, GaN or GaO.

The heat sink 22 includes a first layer 30, an electrically insulating second layer 32 on the first layer 30, and an electrically conductive third layer 34 on the second layer 32. The first layer 30 is a support layer. The first layer 30, the second layer 32 and/or the third layer 34 may be parallel to one another. The first layer 30 and the second layer 32 may completely overlap. Outer edges of the first layer 30 may be flush with outer edges of the second layer 32. The third layer 34 may include two, three, or four or more sections that are separated from each other. Alternatively, the third layer 34 may include only one third layer 34 extending completely over the entire second layer 32, for example. The first layer 30 and/or the third layer 34 may include or be made of copper and/or aluminum. The second layer 32 may include a dielectric material. The heat sink 22 may be a DBC (Direct Bonded Copper) substrate or an IMS (Insulated Metal Substrate).

The arrangement body 26 is arranged between the chip arrangement 24 and the heat sink 22. The arrangement body 26 includes at least one contact recess 50, 52 through which the chip arrangement 24 is thermally coupled to the heat sink 22 by the at least one contact recess. The arrangement body 26 is formed and arranged in such a way that there is a form fit between the arrangement body 26 and the heat sink 22 in a direction extending parallel to at least one of the layers 30, 32, 34 of the heat sink 22. The arrangement body 26 may include or be made of a synthetic material, for example, a synthetic resin. The material of the arrangement body 26 may be resistant to heat, for example, up to temperatures of one hundred degrees (100°) to three hundred degrees (300°) Celsius, for example, from one hundred and fifty degrees (150°) to two hundred and fifty degrees (250°) Celsius, for example, about two hundred degrees (200°) Celsius. The material of the arrangement body 26 may be electrically insulating.

The form fit between the arrangement body 26 and the heat sink 22 may be provided by a heat sink recess 54 in the arrangement body 26, with the heat sink 22 being at least partially arranged in the heat sink recess 54. For example, the second layer 32 and/or the third layer 34 of the heat sink 22 can be arranged completely or partially in the heat sink recess 54. The heat sink 22 may be at least partially arranged in the heat sink recess with a clearance fit or an interference fit between an inner side wall of the heat sink recess 54 and an outer edge of the heat sink 22, especially an outer edge of the second layer 32 of the heat sink 22. The heat sink recess 54 may only extend partially from a first side of the arrangement body 26 to a second side of the arrangement body 26, and may include an inner side wall surrounding a bottom in the arrangement body 26.

Alternatively or additionally, the form fit between the arrangement body 26 and the heat sink 22 may be provided by at least one third layer recess 52 in the arrangement body 26, with at least one section of the third layer 34 of the heat sink 22 being arranged in the third layer recess 52. The corresponding section of the third layer 34 may be at least partially, preferably completely, arranged in the third layer recess 52, with a clearance fit or an interference fit between an inner side wall of the third layer recess 52 and an outer edge of the corresponding section of the third layer 34. If the chip arrangement 24 is thermally coupled to the heat sink 22 by the third layer recess 52, the third layer recess 52 may be equivalent to the contact recess described above. The third layer recess 52 may be a through recess extending from the first side of the arrangement body 26 to the second side of the arrangement body 26. Furthermore, the third layer recess 52 may be arranged in the heat sink recess 54 and/or open into the heat sink recess.

The arrangement body 26 is formed and arranged in such a way that there is a form fit between the arrangement body 26 and the chip arrangement 24 in a direction extending parallel to the carrier 40 of the chip arrangement 24. The direction extending parallel to the layers 30, 32, 34 of the heat sink 22 and the direction extending parallel to the carrier 40 of the chip arrangement 24 may extend parallel to each other.

The form fit between the arrangement body 26 and the chip arrangement 24 may be provided by a recess 50 for an electronic component in the arrangement body 26, with the electronic component 42 of the chip arrangement 24 being at least partially arranged in the recess 50 for the electronic component. The electronic component 42 may be at least partially arranged in the recess 50 for the electronic component with a clearance fit or an interference fit between an inner side wall of the recess 50 for the electronic component and an outer edge of the corresponding electronic component 42. If the chip arrangement 24 is thermally coupled to the heat sink 22 by the recess 50 for the electronic component, the recess 50 for the electronic component may be equivalent to the contact recess. The recess 50 for the electronic component may be a through recess extending from the first side of the arrangement body 26 to the second side of the arrangement body 26.

Alternatively or additionally, the form fit between the arrangement body 26 and the chip arrangement 24 may be provided by at least one pin 56 of the arrangement body 26, which is arranged in a corresponding pin recess 44 in the carrier 40 of the chip arrangement 24. The pin 56 may be arranged at least partially in the pin recess 44 with a clearance fit or an interference fit between an inner side wall of the pin recess 44 and an outer edge of the corresponding pin 56. The pin recess 44 may be a through recess extending from a first side of the carrier 40 to a second side of the carrier 40.

The thermal coupling between the chip arrangement 24 and the heat sink 22 may be provided by direct physical contact between the heat sink 22 and the chip arrangement 24. The direct physical contact between the chip arrangement 24 and the heat sink 22 may be provided the direct physical contact between the carrier 40 of the chip arrangement 24 and the third layer 34 of the heat sink 22. Alternatively or additionally, the direct physical contact between the chip arrangement 24 and the heat sink 22 may be provided by a direct physical contact between the electronic component 42 of the chip arrangement 24 and the third layer 34 of the heat sink 22.

Alternatively or additionally, the thermal coupling between the chip arrangement 24 and the heat sink 22 can be provided by a connecting material (not shown) that firmly couples the chip arrangement 24 to the heat sink 22. The firm connection between the chip arrangement 24 and the heat sink 22 may be provided by a firm connection between the electronic component 42 of the chip arrangement 24 and the third layer 34 of the heat sink 22. If the chip arrangement 24 is thermally coupled to the heat sink by the thermal coupling between the electronic component 42 and the third layer 34 of the heat sink 22, the electronic component 42 may be arranged in the recess 50 for the electronic component of the arrangement body 26. The corresponding recess 50 for the electronic component may be equivalent to the contact recess.

The arrangement body 26 may be formed and arranged in such a way that at least one cavity between the chip arrangement 24 and the heat sink 22 is filled by the arrangement body 26. For example, any cavity between the chip arrangement 24 and the heat sink 22 may be filled by the arrangement body 26. For example, any cavity filled by the arrangement body 26 may be filled completely by the arrangement body 26.

The power module 20 may be embedded in a housing (not shown). The housing may be made of a molding material. In other words, the power module 20 may be molded and/or embedded in a molded body (not shown). For example, the power module 20 may be completely embedded in the molded body.

FIG. 2 shows a top view of the heat sink 22 of the power module 20 according to FIG. 1. It can be seen from FIG. 2 that the heat sink 22 has a rectangular shape and the heat sink 22 includes four sections of the third layer 34, each section having a rectangular shape. Alternatively, the heat sink 22 and/or the sections may have various shapes, for example, any polygonal or circular shapes. Furthermore, the heat sink 22 may include fewer or more sections of the third layer 34.

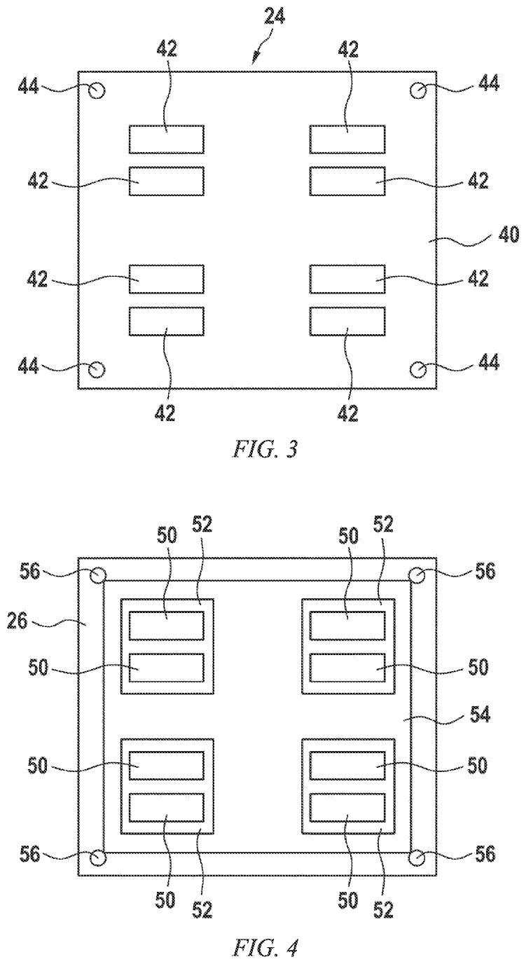

FIG. 3 shows a bottom view of the chip arrangement 24 of the power module 20 according to FIG. 1. It can be seen from FIG. 3 that the chip arrangement 24 has a rectangular shape; the chip arrangement 24 includes four pin recesses 44; and the chip arrangement 24 includes eight electronic components 42. Each pin recess 44 is a through recess and extends from the first side of the chip arrangement 24 to the second side of the chip arrangement 24. Each pin recess 44 may have a circular shape. Each electronic component 42 is arranged on the first side of the chip arrangement 24. Alternatively, the chip arrangement 24 and/or the pin recesses 44 may have various shapes, for example, any polygonal or circular shapes. Furthermore, the chip arrangement 24 may include more or fewer pin recesses 44 and/or electronic components 42, and/or some of the electronic components 42 may be arranged on the second side of the chip arrangement 24.

The electronic components 42 are arranged to overlap the sections of the third layer 34 in an assembled state of the power module 20. For example, in the assembled state of the power module 20, the electronic components 42 may be in direct physical contact with the corresponding sections of the third layer 34 of the heat sink 22, or may be connected to the corresponding sections of the third layer 34 by a connecting material.

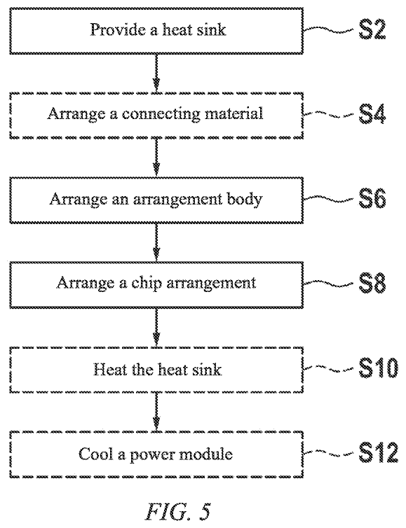

FIG. 4 shows a top view of the arrangement body 26 of the power module 20 according to FIG. 1. It can be seen from FIG. 4 that the arrangement body 26 has a rectangular shape; and the arrangement body 26 includes one heat sink recess 54, four pins 56, four third layer recesses 52 and eight recesses 50 for electronic components. Each of the recesses 50 for electronic components is a through recess and extends completely through the arrangement body 26. The chip arrangement 24 may include more or fewer recesses 50 for electronic components, and the number of recesses corresponds to the number of electronic components 42 of the chip arrangement 24. The recesses 50 for electronic components are arranged such that the electronic components 42 are arranged in the corresponding recesses 50 for electronic components in the assembled state of the power module 20.

Each pin 56 is arranged on the side of the arrangement body 26 facing the chip arrangement 24. Each pin 56 may have a circular shape. The pin 56 is configured to be inserted into the corresponding pin recess 44 of the chip arrangement 24 and to be arranged therein. Alternatively, the chip arrangement 24 and/or the pins 44 may have various shapes, for example, any polygonal or circular shape. The number and the shape of the pins 56 preferably correspond to the number and the shape of the pin recesses 44.

The third layer recesses 52 are configured to at least partially accommodate the corresponding sections of the third layer 34 of the heat sink 22. For example, in the assembled state of the power module 20, the sections of the third layer 34 may be completely arranged in the corresponding third layer recesses 52. The third layer recesses 52 completely overlap the recesses 50 for electronic components. In an alternative implementation, at least one of the recesses 50 for electronic components and the corresponding two third layer recesses 52 may be designed as a single recess.

The heat sink recess 54 is configured to at least partially accommodate the heat sink 22, for example, the second layer 30 and/or the third layer 32 of the heat sink 22. For example, in the assembled state of the power module 20, the second layer 32 can be completely arranged in the corresponding heat sink recess 54. The heat sink recess 54 completely overlaps the third layer recesses 52 and the recesses 50 for electronic components.

In the assembled state of the power module 20, the heat sink recess 54 and the third layer recesses 52 provide the form fit between the heat sink 22 and the arrangement body 26 in the direction extending parallel to at least one of the layers 30, 32, 34 of the heat sink 22. Alternatively, the form fit between the heat sink 22 and the arrangement body 26 may be provided either only by the heat sink recess 54 or only by the third layer recesses 52.

In the assembled state of the power module 20, the pins 56 and the recesses 50 for electronic components provide the form fit between the chip arrangement 24 and the arrangement body 26 in the direction extending parallel to the carrier 40 of the chip arrangement 24. Alternatively, the form fit between the chip arrangement 24 and the arrangement body 26 may be provided either only by the pins 56 or only by the recesses 50 for electronic components.

FIG. 5 shows a flowchart of a method for assembling a power module according to an example embodiment of the present invention (e.g., the power module 20 described above).

In step S2, a heat sink, for example, the heat sink 22 described above, is provided.

In an optional step S4, a connecting material (e.g., the connecting material described above) may be arranged on the heat sink (e.g., arranged above the sections of the third layer 34 of the heat sink 22).

In step S6, an arrangement body (e.g., the arrangement body 26 described above) is arranged on the heat sink 22. Preferably, the arrangement body 26 is arranged on the heat sink 22, such that the heat sink 22 is at least partially arranged in the heat sink recess 54, and that the sections of the third layer 34 are completely arranged in the corresponding recesses 50 for electronic components.

In step S8, a chip arrangement (e.g., the chip arrangement 24 described above) is arranged on the heat sink 26. Preferably, the chip arrangement 24 is arranged on the heat sink 26, such that the pins 56 are accommodated in the corresponding pin recesses 44, and that the electronic components 42 are arranged in the recesses 50 for electronic components. When the connecting material is arranged on the third layer 34 of the heat sink 22 in step S4, the chip arrangement 24 may be arranged on the arrangement body 26 and the heat sink 22, such that the electronic components 42 are in direct physical contact with the connecting material.

In optional step S10, for example, when the connecting material is arranged on the third layer 34 of the heat sink 22 in step S4, the power module 20 can be heated such that the connecting material is melted. To heat the power module 20 and melt the connecting material, the power module 20 may be particularly arranged on a heating plate. The first layer 30 of the heat sink 22 facing away from the chip arrangement 24 is arranged on the heating plate. The heating plate can then heat the heat sink 22. Heat is transferred to the connecting material through the layers 30, 32, 34 of the heat sink 22 and at least partially melts the connecting material.

For example, when the connecting material is melted in step S10, the power module 20 may be cooled in an optional step S12. The melted connecting material is solidified and implements a firm connection between the electronic components 42 and the corresponding sections of the third layer 34 of the heat sink 22.

The power module 20 is then in an assembled state thereof, as shown in FIG. 1. Optionally, the power module 20 may be embedded, for example, completely embedded, in a molded body (not shown).

The present invention is not limited to the above example implementations. For example, there may be more or fewer pins 56 and corresponding pin recesses 44. In addition, the pins 56 may be arranged on the chip arrangement 24, and the corresponding pin recesses 44 may be arranged in the arrangement body 26. Moreover, there may be more or fewer electronic components 42 and corresponding recesses 50 for electronic components. Furthermore, there may be more or fewer sections of the third layer 34 and corresponding third layer recesses 52.

Although the present invention has been illustrated and described in detail in the foregoing description with reference to the drawings, such illustration and description should be considered illustrative or exemplary, rather than restrictive, and the present invention is not limited to the disclosed implementations. Other variations of the disclosed implementations can be understood and implemented by those skilled in the art by practicing the claimed invention, and carefully considering the drawings, the disclosure and the appended claims. In the claims, the word “comprising” does not exclude other elements or steps, and the indefinite article “a/an” does not exclude a plurality. A single processor or a single controller or a single unit may implement the functions of a plurality of elements recited in the claims. The fact that some measures are listed in claims with mutually different dependencies does not mean that a combination of these measures cannot be used to advantage.

Any reference signs in the claims shall not be construed as limiting the scope of protection.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### LIST OF REFERENCE SIGNS

20 Power module
22 Heat sink
24 Chip arrangement
26 Arrangement body
First layer
32 Second layer
34 Third layer
40 Carrier
42 Electronic component
44 Pin recess
50 Recess for electronic component
52 Third layer recess
54 Heat sink recess
56 Pin
S2-S12 Step I to Step XII

1-10. (canceled)

11. A power module (20), comprising:
a chip arrangement (24) with a carrier (40) and at least one electronic component (42) assembled on the carrier (40);
a heat sink (22) with a first layer (30), an electrically insulating second layer (32) located on the first layer (30), and an electrically conductive third layer (34) located on the second layer (32); and
an arrangement body (26) arranged between the chip arrangement (24) and the heat sink (22), the arrangement body (26) defining at least one contact recess (50, 52) through which the chip arrangement (24) is thermally coupled to the heat sink (22), the arrangement body (26) formed and arranged such that a form fit is formed between the arrangement body (26) and the heat sink (22) in a direction extending parallel to at least one of the first, second, and third layers (30, 32, 34) of the heat sink (22) and between the arrangement body (26) and the chip arrangement (24) in a direction extending parallel to the carrier (40) of the chip arrangement (24),
wherein the form fit between the arrangement body (26) and the heat sink (22) is provided by one or both of
a heat sink recess (54) in the arrangement body (26) with the heat sink (22) at least partially arranged in the heat sink recess (54) with a clearance fit or an interference fit between an inner side wall of the heat sink recess (54) and an outer edge of the heat sink (22), and
at least one third layer recess (52) in the arrangement body (26) with at least one section of the third layer (34) of the heat sink (22) arranged in the third layer recess (52) with a clearance fit or an interference fit between an inner side wall of the third layer recess (52) and an outer edge of the corresponding section of the third layer (34).

12. The power module (20) of claim 11, wherein the form fit between the arrangement body (26) and the chip arrangement (24) is provided by one or both of:
a recess (50) for an electronic component in the arrangement body (26) with the electronic component (42) of the chip arrangement (24) at least partially arranged in the recess (50) for the electronic component; and
each of at least one pin (56) of the arrangement body (26) arranged in a corresponding pin recess (44) in the carrier (40) of the chip arrangement (24).

13. The power module (20) of claim 11, wherein the thermal coupling between the chip arrangement (24) and the heat sink (22) is provided by:
direct physical contact between the heat sink (22) and the chip arrangement (24); or
a connecting material that fixedly couples the chip arrangement (24) to the heat sink (22).

14. The power module (20) of claim 11, wherein the arrangement body (26) is formed and arranged such that at least one cavity between the chip arrangement (24) and the heat sink (22) is filled by the arrangement body (26).

15. The power module (20) of claim 11, wherein the heat sink (22) is a directly bonded copper substrate or an insulated metal substrate.

16. The power module (20) of claim 11, wherein the electronic component (42) or at least one further electronic component (42) of the chip arrangement (24) is a high-performance semiconductor chip.

17. A method for manufacturing a power module (20), the method comprising:
providing a heat sink (22) that comprises a first layer (30), an electrically insulating second layer (32) located on the first layer (30), and an electrically conductive third layer (34) located on the second layer (32);
arranging an arrangement body (26) having a contact recess (50, 52) on the heat sink (22), the arrangement body (26) formed and arranged such that a form fit is provided between the arrangement body (26) and the heat sink (22) in a direction extending parallel to at least one of the first, second, and third layers (30, 32, 34) of the heat sink (22); and
arranging a chip arrangement (24) on the arrangement body (26), the chip arrangement (24) comprising a carrier (40) and at least one electronic component (42) assembled on the carrier, the arrangement body (26) and the chip arrangement (24) formed and arranged such that the heat sink (22) and the chip arrangement (24) are thermally coupled by the contact recess (50, 52), a form fit provided between the arrangement body (26) and the chip arrangement (24) in a direction extending parallel to the carrier (40) of the chip arrangement (24),
wherein the form fit between the arrangement body (26) and the heat sink (22) is provided by one or both of
a heat sink recess (54) in the arrangement body (26), the heat sink (22) at least partially arranged in the heat sink recess (54) with a clearance fit or an interference fit between an inner side wall of the heat sink recess (54) and an outer edge of the heat sink (22), and
at least one third layer recess (52) in the arrangement body (26), at least one section of the third layer (34) of the heat sink (22) arranged in the third layer recess (52) with a clearance fit or an interference fit between an inner side wall of the third layer recess (52) and an outer edge of the corresponding section of the third layer (34).

18. The method of claim 17, wherein the form fit between the arrangement body (26) and the heat sink (24) is provided by one or both of:
a recess (50) for an electronic component in the arrangement body (26), the electronic component (42) of the chip arrangement (24) at least partially arranged in the recess (50) for the electronic component; and
at least one pin (56) of the arrangement body (26), each of the at least one pin (56) arranged in a corresponding pin recess (44) in the carrier (40) of the chip arrangement (24).

19. The method of claim 17, wherein the arrangement body (26) is formed and arranged such that at least one cavity between the chip arrangement (24) and the heat sink (22) is filled by the arrangement body (26).

20. The method of claim 17, further comprising:
providing at least one connecting material in a region between the heat sink (22) and the chip arrangement (24) such that the connecting material is in direct physical contact with the heat sink (22) and the chip arrangement (24), the region configured for the thermal coupling between the heat sink (22) and the chip arrangement (24);
heating the first layer (30) of the heat sink (22) such that heat is transferred from the first layer (30) of the heat sink (22) to the connecting material through the second and third layers (32, 34) and at least partially melts the connecting material; and
cooling the power module (20) such that the connecting material solidifies and the chip arrangement (24) is firmly connected to the heat sink (22) via the solidified connecting material.
